(19) United States
(12) Patent Application Publication
(10) Pub. No.: US 2025/0176290 A1
(43) Pub. Date: May 29, 2025

(54) PHOTOSENSITIVE DEVICE AND FORMING METHOD THEREFOR

(71) Applicant: SHANGHAI HUAHONG GRACE SEMICONDUCTOR MANUFACTURING CORPORATION, Shanghai (CN)

(72) Inventor: Lei WANG, Shanghai (CN)

(73) Assignee: SHANGHAI HUAHONG GRACE SEMICONDUCTOR MANUFACTURING CORPORATION, Shanghai (CN)

(21) Appl. No.: 18/876,594

(22) PCT Filed: Aug. 31, 2023
(86) PCT No.: PCT/CN2023/116093

§ 371 Date: Dec. 18, 2024

(30) Foreign Application Priority Data
Mar. 29, 2023 (CN) 202310323409.6

(51) Int. Cl. H10F 39/00

(52) U.S. Cl. CPC H10F 39/8063; H10F 39/024

(57) ABSTRACT

A photosensitive device and a forming method therefor. The photosensitive device comprises: a substrate; a plurality of photosensitive areas located in the substrate; and a lens structure located on each photosensitive area, the lens structure comprising a plurality of layers of micro-lenses which are stacked. The photosensitive device and the forming method therefor enhance the flexibility of the optical design of lens structures, improve the light collection capability of the lens structures, reduce the optical noise in the photosensitive device, simplify the process, and enhance the device performance.

This application claims the benefit of priority to Chinese patent application No. 202310323409.6, filed on Mar. 29, 2023, entitled “PHOTOSENSITIVE DEVICE AND FORMING METHOD THEREFOR”, the entire disclosures of which are incorporated herein by reference.

### TECHNICAL FIELD

The present disclosure generally relates to semiconductor manufacturing technology field, and more particularly to a photosensitive device and a method for forming the photosensitive device.

### BACKGROUND

Complementary Metal Oxide Semiconductor Image Sensor (CMOS image sensor, abbreviated as CIS) is an optical sensor which converts optical signals into electrical signals and converts the electrical signals into digital signals through a readout circuit. CIS is widely used in a vision field and is a core component of a camera module.

Typically, a CIS sensor includes a micro lens, a photosensitive area and a logic device. When the CIS sensor is working, external light is collected through the micro lens. After the light passes through the micro lens and reaches the photosensitive area, photoelectrons are generated through a photoelectric effect in the photosensitive area. The photoelectrons are collected and processed by a circuit to form electrical signals to achieve photoelectric conversion.

However, optical design flexibility and light collection capability of current micro lens still need to be improved, and an optical noise in the device is relatively large, which affects the performance of the device.

### SUMMARY

Embodiments of the present disclosure provide a photosensitive device and a method for forming the photosensitive device, which can improve optical design flexibility of a micro lens, enhance light collection capability, reduce optical noise in the photosensitive device, simplify production process and improve device performance.

An embodiment of the present disclosure provides a photosensitive device. including: a substrate; a plurality of photosensitive areas disposed in the substrate; and a lens structure disposed on each of the plurality of photosensitive areas, wherein the lens structure includes a plurality of stacked layers of micro lenses.

According to some embodiments, a light transmissive dielectric layer is disposed between two adjacent layers of micro lenses, and a refractive index of the light transmissive dielectric layer is less than a refractive index of each layer of micro lenses.

According to some embodiments, each layer of micro lenses has a same or different surface curvature.

According to some embodiments, each layer of micro lenses includes a concave lens or a convex lens.

According to some embodiments, when a total layer number of micro lenses is greater than two, each light transmissive dielectric layer has a same or different thickness.

According to some embodiments, the lens structure includes a plurality of layers of micro lens groups, and each micro lens group includes the plurality of layers of micro lenses.

According to some embodiments, each micro lens group includes two layers of micro lenses including a first micro lens and a second micro lens in direct contact with the first micro lens, and a refractive index of a material of the first micro lens is different from a refractive index of a material of the second micro lens.

According to some embodiments, the refractive index of the material of the first micro lens ranges from 1 to 2, and the refractive index of the material of the second micro lens ranges from 3 to 4.

According to some embodiments, the material of the first micro lens includes silicon oxide, and the material of the second micro lens includes silicon oxide doped with heavy metal ions including chromium ions or manganese ions.

According to some embodiments, when the first micro lens is a convex lens, the second micro lens is a concave lens, and when the first micro lens is a concave lens, the second micro lens is a convex lens.

According to some embodiments, a surface curvature of the first micro lens is different from a surface curvature of the second micro lens.

According to some embodiments, a thickness of the first micro lens is different from a thickness of the second micro lens.

According to some embodiments, when a number of the plurality of layers of micro lens groups is greater than or equal to one, the plurality of layers of micro lens groups are stacked, and a light transmissive dielectric layer is disposed between two adjacent layers of micro lens groups, wherein the plurality of micro lenses in different micro lens groups have a same or different focal length.

According to some embodiments, when a total layer number of micro lenses in each micro lens group is equal to or greater than 1, and the total layer number of micro lenses in different micro lens groups is the same or different.

According to some embodiments, a total layer number of micro lenses in the lens structure on different photosensitive areas is the same or different.

Another embodiment of the present disclosure provides a method for forming a photosensitive device, including: providing a substrate; forming a plurality of photosensitive areas in the substrate; and forming a lens structure on each of the plurality of photosensitive areas, wherein the lens structure includes a plurality of stacked layers of micro lenses.

According to some embodiments, the method further includes: forming a light transmissive dielectric layer between two adjacent layers of micro lenses, wherein a refractive index of the light transmissive dielectric layer is less than a refractive index of each layer of micro lenses.

According to some embodiments, forming each layer of micro lenses and the light transmissive dielectric layer includes: forming a first layer of micro lenses on the plurality of photosensitive areas; and performing a plurality of micro lens cycling processes on the first layer of micro lenses to form a plurality of layers of alternating stacked light transmissive dielectric layer and micro lenses; wherein each of the plurality of micro lens cycling processes includes: depositing the light transmissive dielectric layer; planarizing the light transmissive dielectric layer; and forming a layer of micro lenses on the light transmissive dielectric layer.

According to some embodiments, forming a layer of micro lenses on the light transmissive dielectric layer includes: depositing a micro lens material layer; patterning the micro lens material layer to form a micro lens film; and etching the micro lens film to form the layer of micro lenses.

According to some embodiments, the lens structure includes a plurality of layers of micro lens groups, and each micro lens group includes the plurality of layers of micro lenses.

According to some embodiments, each micro lens group includes two layers of micro lenses including a first micro lens and a second micro lens in direct contact with the first micro lens, and a refractive index of a material of the first micro lens is different from a refractive index of a material of the second micro lens.

According to some embodiments, forming the first micro lens and the second micro lens includes: depositing a first micro lens material layer; patterning the first micro lens material layer to form a first micro lens film; etching the first micro lens film to form the first micro lens; depositing a second micro lens on the first micro lens, wherein the refractive index of the material of the first micro lens is different from the refractive index of the material of the second micro lens.

According to some embodiments, a number of the plurality of micro lens groups is greater than or equal to one, when the number of the plurality of micro lens groups is greater than one, the plurality of layers of micro lens groups are stacked, wherein the method further includes: forming a light transmissive dielectric layer between two adjacent layers of micro lens groups.

Compared with conventional technology, the embodiments of the present disclosure have following advantages.

In the photosensitive device according to the embodiments of the present disclosure, as the lens structure on each photosensitive area includes a plurality of stacked layers of micro lenses, a multi-lens including a plurality of micro lenses is formed on a light path where the light is incident. Compared with traditional single-layered micro lens, the plurality of stacked layers of micro lenses can increase a numerical aperture of the overall lens structure, enhance a light concentration capability and a light collection capability of the lens structure. At the same time, as the lens structure of the multi-lens has better light concentration capability, the light passing through the lens structure can be better concentrated on corresponding photosensitive area of the lens structure, which can reduce an optical interference between different photosensitive areas. Secondly, as the lens structure includes the plurality of layers of micro lenses, the structure, focal length, thickness and other parameters of each layer of micro lenses can be adjusted according to optical design requirements, which can provide more flexibility for the optical design. Further, the lens structure of the multi-lens can reduce an optical interference in the photosensitive device, thus an isolation structure between the photosensitive areas in traditional sensors can be omitted and device costs and complexity can be reduced.

Furthermore, the lens structure includes a plurality of layers of micro lens groups, and each of the plurality of micro lens groups includes the plurality of layers of micro lenses. The focal length of the micro lenses in different micro lens groups is the same or different, and the number of micro lens groups is greater than or equal to one. Therefore, the structure, thickness and focal length of each micro lens in the lens structure have more possible choices, which can enhance the flexibility of the optical design.

In the method for forming the photosensitive device according to the embodiments of the present disclosure, as the lens structure on each photosensitive area includes a plurality of stacked layers of micro lenses, a multi-lens including a plurality of micro lenses is formed on a light path where the light is incident. Compared with traditional single micro lens, the plurality of stacked layers of micro lenses can increase a numerical aperture of the overall lens structure, and enhance a light concentration capability and a light collection capability of the lens structure. At the same time, as the lens structure of the multi-lens has better light concentration capability, the light passing through the lens structure can be better concentrated on corresponding photosensitive area of the lens structure, which can reduce an optical interference between different photosensitive areas. Secondly, as the lens structure includes the plurality of layers of micro lenses, the structure, focal length, thickness and other parameters of each layer of micro lenses can be adjusted according to optical design requirements, which can provide more flexibility for the optical design. Further, the lens structure of the multi-lens can reduce an optical interference in the photosensitive device, thus an isolation structure between the photosensitive areas in traditional sensors can be omitted and device costs and complexity can be reduced.

Furthermore, the lens structure includes a plurality of layers of micro lens groups, and each micro lens group includes a first micro lens and a second micro lens. The second micro lens is directly deposited and formed on the first micro lens to form a multi-lens structure, which can simplify the production process and reduce the production cost.

### BRIEF DESCRIPTION OF THE DRAWINGS

FIGS. 1 to 5 illustrate schematic sectional views showing a method for forming a photosensitive device according to a first embodiment of the present disclosure.

FIGS. 6 to 7 illustrate schematic sectional views showing a method for forming a photosensitive device according to a second embodiment of the present disclosure.

FIGS. 8 to 9 illustrate schematic sectional views showing a method for forming a photosensitive device according to a third embodiment of the present disclosure.

### DETAILED DESCRIPTION

Typically, a CIS sensor includes a micro lens, a photosensitive area and a logic device. When the CIS sensor is working, external light is collected through the micro lens. After the light passes through the micro lens and reaches the photosensitive area, photoelectrons are generated through a photoelectric effect in the photosensitive area. The photoelectrons are collected and processed by a circuit to form electrical signals to achieve photoelectric conversion.

However, existing micro lenses are usually single-layered micro lenses, which have low flexibility, high difficulty in achieving predetermined optical design requirements and poor light collection capability. Secondly, a total optical path distance and direction from a micro lens to a photosensitive area are affected by a dielectric layer in the CIS sensor and an actual shape of the micro lens, which results in scattering of some light and significant optical interference between different photosensitive areas and affects an accuracy of photoelectric conversion. Furthermore, in order to reduce the optical interference between different photosensitive areas, an isolation structure is formed between adjacent photosensitive areas below the micro lens to improve isolation between adjacent photosensitive areas. However, a formation process of the isolation structure increases a process complexity of the CIS sensor.

An embodiment of the present disclosure provides a method for forming a photosensitive device. A lens structure is disposed on each of a plurality of photosensitive areas. As the lens structure on each photosensitive area includes a plurality of stacked layers of micro lenses, a multi-lens including a plurality of micro lenses is formed on a light path where the light is incident. Compared with traditional single-layered micro lens, the plurality of stacked micro lenses can increase a numerical aperture of the overall lens structure, enhance a light concentration capability and a light collection capability of the lens structure, reduce an optical interference between different photosensitive areas, provide more flexibility for the optical design, omit an isolation structure between the photosensitive areas in traditional sensors and reduce production costs.

In order to make above objects, features and advantages of the present disclosure more obvious and understandable, specific embodiments of the present disclosure are described in detail below with reference to the accompanying drawings.

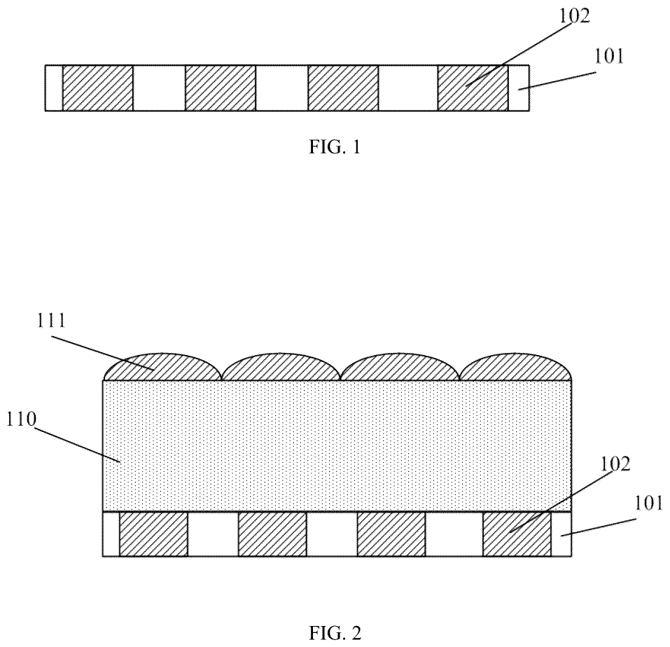

FIGS. 1 to 5 illustrate schematic sectional views showing a method for forming a photosensitive device according to a first embodiment of the present disclosure.

Referring to FIG. 1, a substrate 101 is provided. A plurality of photosensitive areas 102 are formed in the substrate 101.

In some embodiments, the substrate 101 may be formed of a material including silicon, silicon germanium, silicon carbide, silicon on insulator (SOI), germanium on insulator (GOI), etc. Specifically, in some embodiments, the substrate 101 is formed of silicon.

In some embodiments, each photosensitive area 102 includes a diode structure for receiving optical signals and converting optical signals into electrical signals.

In some embodiments, during the operation of the photosensitive device, each photosensitive area 102 works independently and does not interfere with each other.

Referring to FIG. 2, a first dielectric layer 110 is formed on each photosensitive area 102, and a first layer of first micro lenses 111 is formed on the first dielectric layer 110.

In some embodiments, the first dielectric layer 110 is formed of a light transmissive material. Specifically, the first dielectric layer 110 is formed of silicon oxide.

In some embodiments, the first layer of micro lenses 111 may be formed of silicon oxide.

In some embodiments, each photosensitive area 102 corresponds to a micro lens (not labeled) above each photosensitive area 102, and each photosensitive area 102 receives the light passing through corresponding micro lens above each photosensitive area 102.

In some embodiments, the first layer of micro lenses 111 has a circular arc-shaped surface.

Specifically, the method for forming the first layer of micro lenses 111 includes: depositing a first micro lens material layer (not shown) on the first dielectric layer 110, patterning the first micro lens material layer to form a first micro lens film (not shown), and etching the first micro lens film to form the first layer of micro lenses 111.

In some embodiments, the method for etching the first micro lens film includes isotropic etching.

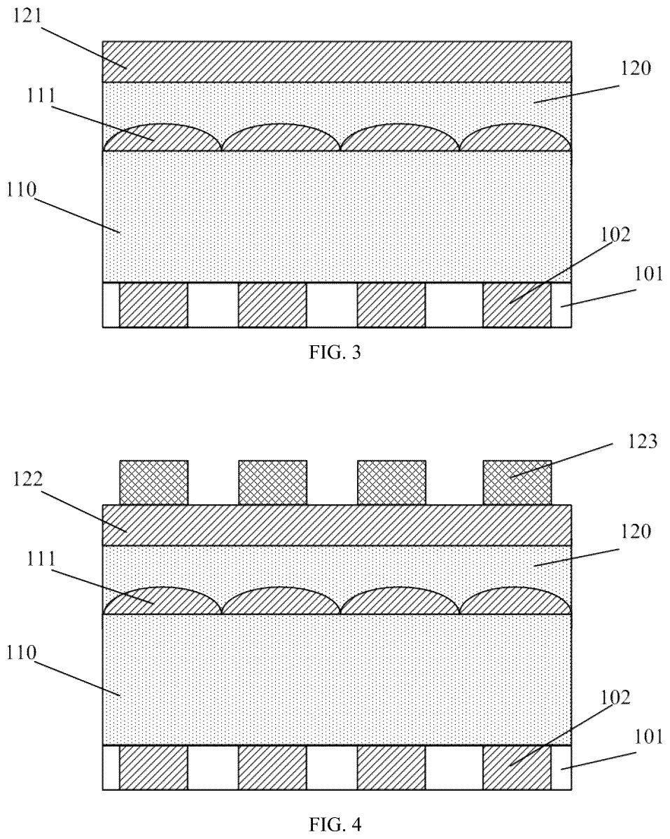

Referring to FIGS. 3, the method further includes: depositing a light transmissive dielectric layer 120 on the first layer of micro lenses 111, planarizing the light transmissive dielectric layer 120, and depositing a second micro lens material layer 121 on the light transmissive dielectric layer 120.

In some embodiments, the second micro lens material layer 121 provides raw materials for the second layer micro lens.

In some embodiments, the second micro lens material layer 121 is formed of a material which is the same or different from a material of the first micro lens layer 111, that is, a refractive index of the second micro lens material layer 121 is the same or different from a refractive index of the first micro lens layer 111.

Referring to FIG. 4, the method further includes: patterning the second micro lens material layer 121 to form a second micro lens film 122, and forming a photoresist layer 123 on the second micro lens film 122.

In some embodiments, the second micro lens film 122 is formed by patterning the second micro lens material layer 121, and a coverage area of the second micro lens film 122 is a micro lens working area. The photoresist layer 123 is used for subsequently etching the second micro lens film 122 to control a surface morphology of subsequently formed second micro lenses.

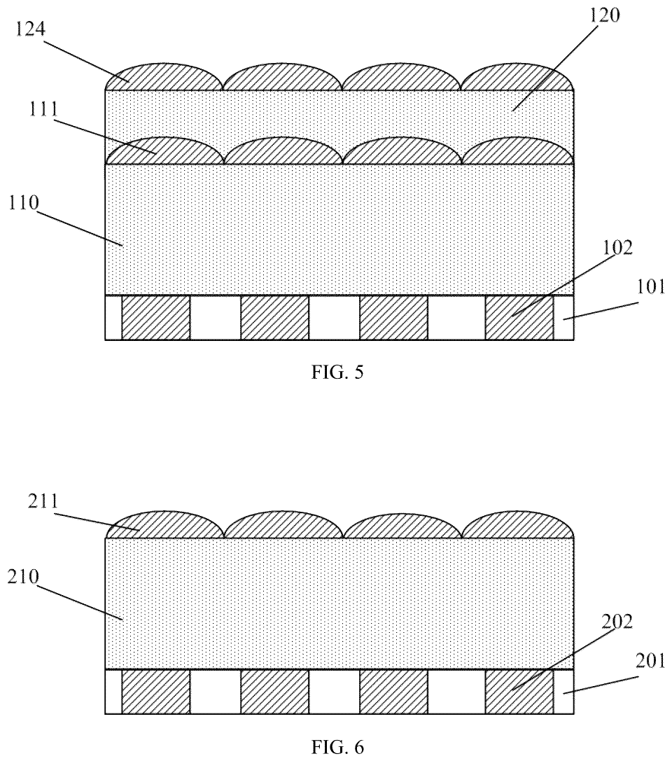

Referring to FIG. 5, the second micro lens film 122 is etched to form a second layer of micro lenses 124.

In some embodiments, the method of etching the second micro lens film 122 includes isotropic etching.

In some embodiments, a surface curvature of the second layer of micro lenses 124 is the same as a surface curvature of the first layer of micro lenses 111. The second layer of micro lenses 124 includes a convex lens, and the first layer of micro lenses 111 also includes a convex lens.

In some embodiments, the first layer of micro lenses 111 and the second layer of micro lenses 124 on the photosensitive area 102 together form a lens structure (not labeled), and the first layer of micro lenses 111 and the second layer of micro lenses 124 are stacked.

In some embodiments, a refractive index of the light transmissive dielectric layer 120 is less than a refractive index of the first layer of micro lenses 111 and the second layer of micro lenses 124.

In some embodiments, the surface curvature of the second layer of micro lenses is the same or different from the surface curvature of the first layer of micro lenses. The second layer of micro lenses includes a concave lens or a convex lens, and the first layer of micro lenses includes a concave lens or a convex lens.

In some embodiments, the lens structure formed on each photosensitive area includes a plurality of stacked layers of micro lenses, and a total layer number of the plurality of layers of micro lenses is greater than two.

In some embodiments, the surface curvature of each layer of micro lenses is different or the same, and each layer of micro lenses includes a concave lens or a convex lens. The refractive index of each layer of micro lenses is the same or different.

In some embodiments, the method for forming the photosensitive device further includes: forming a light transmissive dielectric layer between two adjacent layers of micro lenses. The refractive index of the light transmissive dielectric layer is less than the refractive index of each layer of micro lenses. The thickness of each light transmissive dielectric layer is the same or different.

In some embodiments, the method for forming each layer of micro lenses and the light transmissive dielectric layer includes: forming a first layer of micro lenses on the plurality of photosensitive areas, performing a plurality of micro lens cycling processes on the first layer of micro lenses to form a plurality of layers of alternating stacked light transmissive dielectric layer and micro lenses. The micro lens cycling process includes: depositing the light transmissive dielectric layer, planarizing the light transmissive dielectric layer; and forming a layer of micro lenses on the light transmissive dielectric layer.

In some embodiments, forming a layer of micro lenses on the light transmissive dielectric layer includes: depositing a micro lens material layer; patterning the micro lens material layer to form a micro lens film; and etching the micro lens film to form the layer of micro lenses.

In some embodiments, the method of etching the micro lens film includes isotropic etching. By changing etching time, etching gas composition and a size of the photoresist layer in the etching process, a surface morphology of the formed micro lenses can be controlled to meet the surface curvature requirements of different micro lenses.

In some embodiments, since the first layer of micro lenses and the second layer of micro lenses are formed separately and structures and morphologies of the first layer of micro lenses and the second layer of micro lenses do not affect each other, the structures and morphologies of the first layer of micro lenses and the second layer of micro lenses can be controlled through different processes, which can further increase the flexibility of the structures of the first layer of micro lenses and the second layer of micro lenses, and meet more optical design requirements.

As described above, as the lens structure on each photosensitive area of the photosensitive device includes a plurality of stacked layers of micro lenses, a multi-lens including a plurality of micro lenses is formed on a light path where the light is incident. Compared with traditional single-layered micro lens, the plurality of stacked layers of micro lenses can increase a numerical aperture of the overall lens structure, enhance a light concentration capability and a light collection capability of the lens structure. At the same time, as the lens structure of the multi-lens has better light concentration capability, the light passing through the lens structure can be better concentrated on corresponding photosensitive area of the lens structure, which can reduce an optical interference between different photosensitive areas. Secondly, as the lens structure includes the plurality of layers of micro lenses, the structure, focal length, thickness and refractive index of each layer of micro lenses and the thickness of each light transmissive dielectric layer can be adjusted according to optical design requirements, which can provide more flexibility for the optical design. Further, the lens structure of the multi-lens can reduce an optical interference in the photosensitive device, thus an isolation structure between the photosensitive areas in traditional sensors can be omitted and device costs and complexity can be reduced.

Accordingly, another embodiment of the present disclosure provides a photosensitive device formed by the method shown in FIGS. 1 to 5.

Referring to FIG. 5, the photosensitive device includes a substrate 101, a plurality of photosensitive areas 102 disposed in the substrate 101, a first dielectric layer 110 disposed on each photosensitive area 102 and a lens structure (not labeled) disposed on the first dielectric layer 110. The lens structure includes a plurality of stacked layers of micro lenses (not labeled).

In some embodiments, the lens structure includes two layers of micro lenses, namely a first layer of micro lenses 111 disposed on the first dielectric layer 110 and a second layer of micro lenses 124 disposed on the first layer of micro lenses 111. A light transmissive dielectric layer 120 is disposed between the first layer of micro lenses 111 and the second layer of micro lenses 124, and a refractive index of the light transmissive dielectric layer 120 is less than a refractive index of each layer of micro lenses.

In some embodiments, a surface curvature of the second layer of micro lenses 124 is the same as a surface curvature of the first layer of micro lenses 111. The second layer of micro lenses 124 includes a convex lens, and the first layer of micro lenses 111 also includes a convex lens.

In some embodiments, the lens structure formed on each photosensitive area includes a plurality of stacked layers of micro lenses, and a total layer number of the plurality of layers of micro lenses is greater than or equal to two.

In some embodiments, the surface curvature of each layer of micro lenses is different or the same. Each layer of micro lenses includes a concave lens or a convex lens. The refractive index of layer of micro lenses is the same or different.

In some embodiments, a light transmissive dielectric layer is disposed between two adjacent layers of micro lenses, and a refractive index of the light transmissive dielectric layer is less than the refractive index of each layer of micro lenses. When the total layer number of the micro lens is greater than two, the thickness of each light transmissive dielectric layer is the same or different.

In some embodiments, the total layer number of the micro lens in each lens structure on different photosensitive areas 102 is the same.

In some embodiments, the total layer number of the micro lens in each lens structure on different photosensitive areas 102 is different.

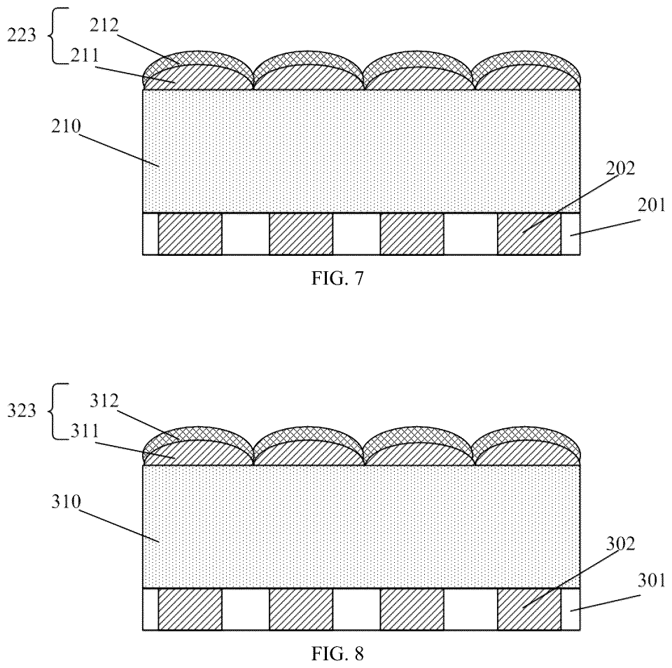

FIGS. 6 to 7 illustrate schematic sectional structural views showing a method for forming a photosensitive device according to a second embodiment of the present disclosure.

Referring to FIG. 6, the method includes: providing a substrate 201, forming a plurality of photosensitive areas 202 in the substrate 201, forming a first dielectric layer 210 on the photosensitive areas 202, and forming a first micro lens 211 on the first dielectric layer 210.

In some embodiments, the materials and methods for forming the substrate 201, the photosensitive areas 202 and the first dielectric layer 210 are the same as those for forming the substrate 101, the photosensitive areas 102 and the first dielectric layer 110 in the first embodiment shown in FIGS. 1 to 5, and thus will not be repeated herein.

In some embodiments, the method for forming the first micro lens 211 includes depositing a first micro lens material layer (not shown) on the first dielectric layer 210, patterning the first micro lens material layer to form a first micro lens film (not shown), and etching the first micro lens film to form the first micro lens 211.

The process of etching the first micro lens film is isotropic etching.

Referring to FIG. 7, a second micro lens 212 is deposited on a surface of the first micro lens 211, and the second micro lens 212 is in direct contact with the surface of the first micro lens 211. A refractive index of a material of the first micro lens 211 is different from a refractive index of a material of the second micro lens 212.

In some embodiment, by selecting the materials of the first micro lens 211 and the second micro lens 212 having a significant refractive index difference, the first micro lens 211 and the second micro lens 212 in contact with each other can form a multi-lens structure.

In some embodiments, the refractive index of the first micro lens 211 is less than the refractive index of the second micro lens 212. The refractive index difference between the first micro lens 211 and the second micro lens 212 is determined as follows. Firstly, the first micro lens 211 is formed, and a numerical aperture NAb and a refractive index n1 of the first micro lens 211 are obtained. Next, a critical incident angle B of light that can be collected by the first micro lens 211 is obtained, where sin B=NAb/n1. Then, based on the critical incident angle B, a total reflection angle A of an interface between the first micro lens 211 and the second micro lens 212 is obtained. When the critical incident angle B is less than the total reflection angle A of the interface, the light that enters the first micro lens 211 from the second micro lens 212 can enter and be collected by the first micro lens 211, that is, A>B shall be satisfied. Finally, based on the total reflection angle A and the refractive index n1 of the first micro lens 211, a refractive index n2 of the second micro lens 212 is obtained, where n2=sin A*n1. By selecting the refractive index n2 of the second micro lens 212 and the refractive index n1 of the first micro lens 211 through above method, the first micro lens 211 and the second micro lens 212 in contact with each other can form a multi-lens structure, which can enhance the light collection capacity. The greater the refractive index difference between the first micro lens 211 and the second micro lens 212, the more stable the multi-lens structure can be formed.

Specifically, in some embodiments, the refractive index of the material of the first micro lens 211 ranges from 1 to 2, and the refractive index of the material of the second micro lens 212 ranges from 3 to 4.

In some embodiments, the refractive index of the first micro lens may also be greater than the refractive index of the second micro lens. By selecting appropriate materials, the refractive index difference between the first micro lens and the second micro lens can be controlled to form a stable multi-lens structure.

In some embodiments, the material of the first micro lens 211 includes silicon oxide, and the material of the second micro lens 212 includes silicon oxide doped with heavy metal ions including chromium ions or manganese ions. By changing a concentration of the doped heavy metal ions, the refractive index of the second micro lens 212 can be controlled to adjust a relative difference from the refractive index of the first micro lens 211.

In some embodiments, a thickness of the first micro lens 211 is different from a thickness of the second micro lens 212, and a surface curvature of the first micro lens 211 is different from a surface curvature of the second micro lens 212. The first micro lens 211 is a convex lens, and the second micro lens 212 is a concave lens. In some embodiments, the first micro lens may be a concave lens, and the second micro lens may be a convex lens.

In some embodiments, the first micro lens 211 and the second micro lens 212 have a significant refractive index difference, thus the stacked first micro lens 211 and second micro lens 212 form a multi-lens structure, which can increase the numerical aperture of the micro lens, enhance a light concentration capability and a light collection capability, reduce an optical interference between different photosensitive areas 202, and provide more flexibility for optical design. In addition, an isolation structure between the photosensitive areas in traditional sensors can be omitted and device costs and complexity can be reduced.

In some embodiments, the second micro lens 212 is directly deposited on the surface of the first micro lens 211 to form a multi-lens structure. Therefore, compared with the first embodiment of the present disclosure, the light transmissive dielectric layer between the first micro lens 211 and the second micro lens 212 can be omitted in the second embodiment, and the second micro lens 212 is formed by direct deposition, which can eliminate the etching and patterning processes for forming the second micro lens 212, simplify a production process and reduce a production cost.

In some embodiments, by controlling a deposition thickness of the second micro lens 212 on the surface of the first micro lens 211, the surface curvature and focal length of the second micro lens 212 can be controlled to meet different optical design requirements.

In some embodiments, the first micro lens 211 and the second micro lens 212 form a layer of micro lens group 233, and the micro lens group 233 is the lens structure (not labeled) on each photosensitive area 202.

In some embodiments, a total layer number of the micro lenses on the photosensitive areas is greater than 2. Each layer of micro lenses are stacked and placed, and two adjacent micro lenses are in direct contact with each other. The refractive indices of the materials of two adjacent micro lenses are different, thus the combination of the micro lenses forms a multi-lens structure.

Accordingly, another embodiment of the present disclosure provides a photosensitive device formed by the method shown in FIGS. 6 to 7.

Referring to FIG. 7, the photosensitive device includes a substrate 201, a plurality of photosensitive areas 202 disposed in the substrate 201, a first dielectric layer 210 disposed on each photosensitive area 202, and a lens structure (not labeled) disposed on the first dielectric layer 210. The lens structure includes a layer of micro lens groups 233, and each micro lens group 233 includes two layers of micro lenses. The two layers of micro lenses include a first micro lens 211 and a second micro lens 212 in direct contact with the first micro lens 211. A refractive index of a material of the first micro lens 211 is different from a refractive index of a material of the second micro lens 212.

In some embodiments, the refractive index of the material of the first micro lens 211 ranges from 1 to 2, and the refractive index of the material of the second micro lens 212 ranges from 3 to 4. Specifically, the material of the first micro lens 211 includes silicon oxide, and the material of the second micro lens 212 includes silicon oxide doped with heavy metal ions including chromium ions or manganese ions.

In some embodiments, a thickness of the first micro lens 211 is different from a thickness of the second micro lens 212, and a surface curvature of the first micro lens 211 is different from a surface curvature of the second micro lens 212. When the first micro lens 211 is a convex lens, the second micro lens 212 is a concave lens, and when the first micro lens 211 is a concave lens, the second micro lens 212 is a convex lens.

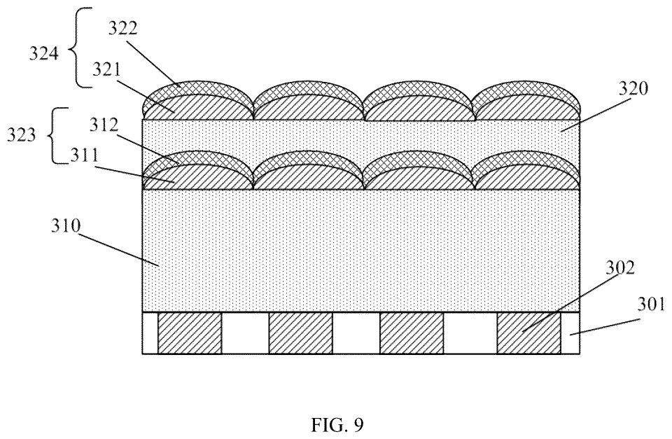

FIGS. 8 to 9 illustrate schematic sectional structural views showing a method for forming a photosensitive device according to a third embodiment of the present disclosure.

Referring to FIG. 8, the method includes: providing a substrate 301, forming a plurality of photosensitive areas 302 in the substrate 301, forming a first dielectric layer 310 on each photosensitive area 302, and forming a first micro lens group 323 on the first dielectric layer 310.

In some embodiments, the first micro lens group 323 includes two layers of micro lenses, namely a first micro lens 311 and a second micro lens 312 in direct contact with the first micro lens 311. A refractive index of a material of the first micro lens 311 is different from a refractive index of a material of the second micro lens 312.

In some embodiments, the materials, structures and methods for forming the substrate 301, the photosensitive areas 302, the first dielectric layer 210, the first micro lens 311 and the second micro lens 312 are the same as those for forming the substrate 201, the photosensitive areas 202, the first dielectric layer 210, the first micro lens 211 and the second micro lens 212 in the second embodiment shown in FIGS. 6 and 7, and thus will not be repeated herein.

Referring to FIG. 9, a light transmissive dielectric layer 320 is formed on a surface of the first micro lens group 323, and a second micro lens group 324 is formed on the light transmissive dielectric layer 320. The second micro lens group 324 includes two layers of micro lenses, namely a first micro lens 321 and a second micro lens 322 in direct contact with the first micro lens 321. A refractive index of a material of the first micro lens 321 is different from a refractive index of a material of the second micro lens 322.

The method for forming the second micro lens group 324 is the same as the method for forming the first micro lens group 323 as shown in FIG. 8, and thus will not be repeated herein.

In some embodiments, the surface curvature, thickness, and refractive index of each layer of micro lenses in the first micro lens group 323 and the second micro lens group 324 may be the same or different, and the focal length of each layer of micro lenses may be the same or different.

In some embodiments, the first micro lens group 323 and the second micro lens group 324 stacked together form a lens structure (not labeled) on each photosensitive area 302, and the lens structure is a multi-lens structure composed of four stacked layers of micro lenses. Compared with traditional single-layered micro lens, the plurality of stacked layers of micro lenses can increase a numerical aperture of the overall lens structure, enhance a light concentration capability and a light collection capability of the lens structure. At the same time, as the lens structure of the multi-lens has better light-concentration capability, the light passing through the lens structure can be better concentrated on corresponding photosensitive area of the lens structure, which can reduce an optical interference between different photosensitive areas. Secondly, since the surface curvature, thickness, and refractive index of each layer of micro lenses in the first lens group and the second micro lens group may be the same or different, the structure, thickness, refractive index and focal length of each layer of micro lenses in the lens structure can be adjusted according to optical design needs, which can enhance the flexibility of optical design. Further, the lens structure of the multi-lens can reduce an optical interference in the photosensitive device, thus an isolation structure between the photosensitive areas in traditional sensors can be omitted and device costs and complexity can be reduced.

In some embodiments, the first micro lens group 323 and the second micro lens group 324 include the same number of layers of micro lenses, and both include two layers of micro lenses.

In some embodiments, the lens structure includes two layers of micro lens groups, and each micro lens group includes one or more layers of micro lenses, and different micro lens groups includes the same or different number of layers of micro lenses. Specifically, the lens structure includes a first micro lens group and a second micro lens group. The first micro lens group may include two layers of micro lenses including a convex lens and a concave lens and a combination thereof. The second micro lens group may include one layer of micro lenses including a concave lens or a convex lens. Similarly, the first micro lens group may include one layer of micro lenses including a concave lens or a convex lens. The second micro lens may include two layers of micro lenses, which may be a combination of a convex lens and a concave lens. The number of the micro lens of the micro lens group may be any natural number greater than or equal to 1.

In some embodiments, when the total layer number of the micro lenses in the micro lens group is greater than or equal to two, each layer of micro lenses are stacked and placed, and two adjacent micro lenses are in direct contact with each other. The refractive indices of the materials of two adjacent micro lenses are different, thus the combination of each micro lens form a multi-lens structure.

In some embodiments, the lens structure on each photosensitive area includes a plurality of layers of micro lens groups, and the number of the micro lens groups is greater than two. Each micro lens group includes two micro lenses, including a first micro lens and a second micro lens in direct contact with the first micro lens. The refractive index of the material of the first micro lens is different from the refractive index of the material of the second micro lens. When the first micro lens is a convex lens, the second micro lens is a concave lens, and when the first micro lens is a concave lens, the second micro lens is a convex lens.

In some embodiments, the plurality of layers of micro lens groups are stacked and placed, and a light transmissive dielectric layer is formed between two adjacent layers of micro lens groups. The surface curvature, thickness, and focal length of the micro lenses in different micro lens groups are the same or different. The thickness of each light transmissive dielectric layer is the same or different. In other embodiments, the total layer number of the micro lenses in each micro lens group may be equal to or greater than one, and the total layer number of the micro lenses in different micro lens groups may be the same or different.

As the lens structure on the photosensitive area includes a plurality of stacked layers of micro lens groups, and each micro lens group includes a plurality of stacked layers of micro lenses, the total layer number of the micro lens in the lens structure can be increased, which can increase the numerical aperture of the overall lens structure, enhance a light concentration capability and a light collection capability of the lens structure, and reduce an optical interference between different photosensitive areas. In addition, the surface curvature, thickness, refractive index, focal length and thickness of each light transmissive dielectric layer, and the total layer number of the micro lenses in each micro lens group can be adjusted according to optical design needs, which can provide more flexibility for optical design and optimize the light transmissivity and the light concentration capability of the lens structure, thereby improving the performance of the photosensitive device.

In some embodiments, the lens structures on different photosensitive areas 302 have different layer number of micro lens.

In some embodiments, the total layer number of the micro lens in the lens structure on different photosensitive areas may be different, which can further increase the optical flexibility of the lens structure.

Correspondingly, an embodiment of the present disclosure also provides a photosensitive device formed by the method as shown in FIGS. 8 and 9.

Referring to FIG. 9, the photosensitive device includes a substrate 301, a plurality of photosensitive areas 302 disposed in the substrate 301, a first dielectric layer 310 disposed on each photosensitive area 302, and a lens structure (not labeled) disposed on the first dielectric layer 310. The lens structure includes a plurality of layers of micro lens groups, and each micro lens group includes a plurality of layers of micro lenses.

Specifically, in some embodiments, the lens structure includes two layers of micro lens groups, namely a first micro lens group 323 and a second micro lens group 324.

In some embodiments, each micro lens group includes two layers of micro lenses, namely a first micro lens and a second micro lens in direct contact with the first micro lens. A refractive index of a material of the first micro lens is different from a refractive index of a material of the second micro lens. Specifically, the first micro lens group 323 includes a first micro lens 311 and a second micro lens 312, and the second micro lens group 324 includes a first micro lens 321 and a second micro lens 322.

In some embodiments, when the first micro lens in the micro lens group is a convex lens, the second micro lens in the same micro lens group is a concave lens, and when the first micro lens in the micro lens group is a concave lens, the second micro lens in the same micro lens group is a convex lens. The surface curvature and thickness of the first micro lens and the second micro lens are different.

In some embodiments, the first micro lens group 323 and the second micro lens group 324 are stacked and placed, and a light transmissive dielectric layer 320 is disposed between the first micro lens group 323 and the second micro lens group 324.

In some embodiments, the total layer number of the micro lens groups is greater than or equal to two, and the plurality of layers of micro lens groups are stacked and placed, and a light transmissive dielectric layer is disposed between two adjacent layers of micro lens groups. The total layer number of the micro lenses in each micro lens group may be equal to or greater than one, and the total layer number the micro lenses in different micro lens groups may be the same or different. The refractive index, surface curvature, thickness and focal length of the micro lenses in different micro lens groups may be the same or different. When the total layer number of the micro lens groups is greater than two, the thickness of each light transmissive dielectric layer is the same or different.

In some embodiments, the lens structures on different photosensitive areas 302 may have the same layer number of micro lenses.

In some embodiments, the lens structures on different photosensitive areas may have different layer number of micro lenses.

Although the present disclosure has been disclosed above, the present disclosure is not limited thereto. Any changes and modifications may be made by those skilled in the art without departing from the spirit and scope of the present disclosure, and the scope of the present disclosure should be determined by the appended claims.

1. A photosensitive device, comprising:
a substrate;
a plurality of photosensitive areas disposed in the substrate; and
a lens structure disposed on each of the plurality of photosensitive areas, wherein the lens structure comprises a plurality of stacked layers of micro lenses.

2. The photosensitive device according to claim 1, wherein a light transmissive dielectric layer is disposed between two adjacent layers of micro lenses, and a refractive index of the light transmissive dielectric layer is less than a refractive index of each micro lens.

3. (canceled)

4. The photosensitive device according to claim 2, wherein each layer of micro lenses comprises a concave lens or a convex lens.

5. (canceled)

6. The photosensitive device according to claim 1, wherein the lens structure comprises a plurality of layers of micro lens groups, and each micro lens group comprises the plurality of layers of micro lenses.

7. The photosensitive device according to claim 6, wherein each micro lens group comprises two layers of micro lenses comprising a first micro lens and a second micro lens in direct contact with the first micro lens, and a refractive index of a material of the first micro lens is different from a refractive index of a material of the second micro lens.

8. The photosensitive device according to claim 7, wherein the refractive index of the material of the first micro lens ranges from 1 to 2, and the refractive index of the material of the second micro lens ranges from 3 to 4.

9. The photosensitive device according to claim 8, wherein the material of the first micro lens comprises silicon oxide, and the material of the second micro lens comprises silicon oxide doped with heavy metal ions comprising chromium ions or manganese ions.

10. The photosensitive device according to claim 7, wherein when the first micro lens is a convex lens, the second micro lens is a concave lens, and when the first micro lens is a concave lens, the second micro lens is a convex lens.

11. The photosensitive device according to claim 7, wherein a surface curvature of the first micro lens is different from a surface curvature of the second micro lens; and/or
a thickness of the first micro lens is different from a thickness of the second micro lens.

12. (canceled)

13. The photosensitive device according to claim 6, wherein when a number of the plurality of layers of micro lens groups is greater than or equal to one, the plurality of layers of micro lens groups are stacked, and a light transmissive dielectric layer is disposed between two adjacent layers of micro lens groups, wherein the plurality of micro lenses in different micro lens groups have a same or different focal length.

14. The photosensitive device according to claim 6, wherein when a total layer number of micro lenses in each micro lens group is equal to or greater than 1, and the total layer number of micro lenses in different micro lens groups is the same or different.

15. The photosensitive device according to claim 1, wherein a total layer number of micro lenses in the lens structure on different photosensitive areas is the same or different.

16. A method for forming a photosensitive device according to claim 1, comprising:
providing the substrate;
forming the plurality of photosensitive areas in the substrate; and
forming the lens structure on each of the plurality of photosensitive areas, wherein the lens structure comprises a plurality of stacked layers of micro lenses.

17. The method according to claim 16, further comprising: forming a light transmissive dielectric layer between two adjacent layers of micro lenses, wherein a refractive index of the light transmissive dielectric layer is less than a refractive index of each of the plurality of micro lenses.

18. The method according to claim 17, wherein forming each layer of micro lenses and the light transmissive dielectric layer comprises:
forming a first layer of micro lenses on the plurality of photosensitive areas; and
performing a plurality of micro lens cycling processes on the first layer of micro lenses to form a plurality of layers of alternating stacked light transmissive dielectric layer and micro lenses;
wherein each of the plurality of micro lens cycling processes comprises:
depositing the light transmissive dielectric layer;
planarizing the light transmissive dielectric layer; and
forming a layer of micro lenses on the light transmissive dielectric layer.

19. The method according to claim 18, wherein forming a layer of micro lenses on the light transmissive dielectric layer comprises:
depositing a micro lens material layer;
patterning the micro lens material layer to form a micro lens film; and
etching the micro lens film to form the layer of micro lenses.

20. The method according to claim 16, wherein the lens structure comprises a plurality of layers of micro lens groups, and each micro lens group comprises the plurality of layers of micro lenses.

21. The method according to claim 20, wherein each micro lens group comprises two layers of micro lenses comprising a first micro lens and a second micro lens in direct contact with the first micro lens, and a refractive index of a material of the first micro lens is different from a refractive index of a material of the second micro lens.

22. The method according to claim 21, wherein forming the first micro lens and the second micro lens comprises:
depositing a first micro lens material layer;
patterning the first micro lens material layer to form a first micro lens film;
etching the first micro lens film to form the first micro lens;
depositing a second micro lens on the first micro lens, wherein the refractive index of the material of the first micro lens is different from the refractive index of the material of the second micro lens.

23. The method according to claim 20, wherein a number of the plurality of micro lens groups is greater than or equal to one, when the number of the plurality of micro lens groups is greater than one, the plurality of layers of micro lens groups are stacked, wherein the method further comprises: forming a light transmissive dielectric layer between two adjacent layers of micro lens groups.
